(19) United States
(12) Patent Application Publication
(10) Pub. No.: US 2021/0293620 A1
(43) Pub. Date: Sep. 23, 2021

(54) Spectrometer and Method for Calibrating the Spectrometer

(71) Applicant: Robert Bosch GmbH, Stuttgart (DE)

(72) Inventors: Martin Husnik, Stuttgart (DE); Martin Dinser, Wuxi (CN); Marc Schmid, Stuttgart (DE); Dominik Uhlich, Zella-Mehlis (DE)

(21) Appl. No.: 17/264,035

(22) PCT Filed: Jul. 23, 2019
(86) PCT No.: PCT/EP2019/069745

§ 371 Date: Jan. 28, 2021

(30) Foreign Application Priority Data
Aug. 9, 2018 (DE) 10 2018 213 377.8

(51) Int. Cl. G01J 3/02; H01L 33/48; H01L 33/50; H01L 33/58; H01L 33/60; G01J 3/28; G01J 3/10

(52) U.S. Cl. CPC G01J 3/0297; H01L 33/486; H01L 33/504; H01L 33/58; G01J 2003/283; G01J 3/0256; G01J 3/28; G01J 3/108; H01L 2933/0091; H01L 33/60

(57) ABSTRACT

The disclosure relates to a spectrometer, comprising: an illumination device for illuminating a spectrometric measurement region; a detection unit for detecting electromagnetic radiation coming from the spectrometric measurement region; and a spectral element, which is arranged in the beam path between the illumination device and the detection unit. The illumination device comprises: a light emitting diode having a first central wavelength, which is designed to emit first electromagnetic radiation having a first spectrum; and a luminescent element for converting a first component of the first electromagnetic radiation having the first spectrum into second electromagnetic radiation having a second spectrum. The first central wavelength is 550 nm or 3000 nm or has a value between 550 nm and 3000 nm. The first spectrum and the second spectrum have an overlap.

### PRIOR ART

US 2016/0091367 A1 describes a broadband NIR (NIR=near infrared) light source for spectroscopy applications, which comprises a blue LED and a luminescent element, radiation emitted by the LED illuminating a sample, which is intended to be spectroscopically studied, after passing through the luminescent element.

For conventional illumination technology, light-emitting diodes (LEDs) in combination with a phosphor are currently being used increasingly. Conventionally, the LED as the active component part emits blue light in the wavelength range of about 450 nanometers (nm) to 470 nm, with a full-width at half-maximum of approximately 30 nm to 40 nm. In order to generate the desired white light, a passive yellow-emitting phosphor, for example consisting of cerium-doped yttrium aluminum garnet, is for example applied onto the surface of the LED (J. Li et al.: A new rare-earth-free hybrid phosphor for efficient solid-state lighting, ACS Annual Meeting Boston, 2015). The phosphor converts the incident blue light of the LED partially into a broad yellow light spectrum. The mixture of the blue light and the broad yellow light spectrum is finally perceived as white light. Blue-emitting LEDs as a supply of high-energy light provide the basis for the so-called down-conversion of the light to lower energies in the phosphor.

For white-light LEDs, or the corresponding phosphors, besides the energy efficiency, criteria such as the color quality (represented by correlated color temperature and color rendering index) and the color temperature are currently central. The color quality and the color temperature may be flexibly adapted application-specifically, and are established inter alia by the ratio of unconverted blue light and converted phosphor spectrum.

The efficiency of modern blue LEDs is typically about 70%, and is limited merely by the development of heat. Additional losses due to application of a phosphor may primarily be attributed to heat losses in the phosphor and to the so-called Stokes loss.

For illumination purposes, the unconverted blue light of the LED contributes to the color effect of the phosphor. In spectrometry applications, only the light fraction converted by the phosphor is used.

### CORE AND ADVANTAGES OF THE INVENTION

In spectrometry, the sample to be analyzed, i.e. the spectrometric measurement region to be studied, is irradiated with electromagnetic radiation from a broad wavelength spectrum. The greater the wavelength range to be studied is, the better the results usually are and the larger the application range usually is. The spectrum coming from the spectrometric measurement region is recorded and evaluated. Often, measurements with spectrometers are carried out in a wavelength interval of about 600 nm to 1100 nm.

For spectrometry, broadband light sources are used which cover the entire relevant spectral range, which is intended to be taken into account in the measurement, with a maximally constant intensity or maximally constant power. In particular for portable instruments, so-called miniature spectrometers, high efficiencies of the light sources are furthermore of great importance.

The invention relates to a spectrometer and to a method for calibrating the spectrometer.

One advantage of the invention having the features of the independent patent claims is that the wavelength interval usable for the spectrometric measurement can be broadened, and that wavelength calibration and/or power calibration can be carried out in a straightforward way.

This is achieved with a spectrometer as claimed in claim 1, which comprises an illumination device for illuminating a spectrometric measurement region, a detection unit for detecting electromagnetic radiation coming from the spectrometric measurement region, and a spectral element which is arranged in the beam path between the illumination device and the detection unit. The illumination device in this case comprises a light-emitting diode having a first central wavelength, which is adapted to emit first electromagnetic radiation having a first spectrum. The illumination device furthermore comprises a luminescent element for converting a first fraction of the first electromagnetic radiation having the first spectrum into second electromagnetic radiation having a second spectrum.

The spectrometer is distinguished in that the first central wavelength of the light-emitting diode is 550 nanometers (nm) or 3000 nm or has a value between 550 nm and 3000 nm, and in that the first spectrum and the second spectrum have an overlap.

The emission spectrum of the illumination device of the spectrometer, which may be used for illuminating the spectrometric measurement region for the spectrometric measurement, consequently advantageously comprises an unconverted second fraction of the first electromagnetic radiation and the second electromagnetic radiation having the second spectrum. One advantage is that a spectrometer having an illumination device is therefore provided, the illumination device offering a broad spectral range in the near infrared wavelength range with a maximally constant power, since the spectrum of the LED already comprises wavelength ranges usable for the spectrometry before the partial conversion by the luminescent element. Because of the high intensity of the electromagnetic radiation emitted by the illumination device, it is possible to achieve a high signal-to-noise ratio (SNR) so that the sensitivity and the accuracy of the spectrometer may advantageously be increased. Furthermore, both the electromagnetic radiation emitted by the light-emitting diode, which is not however converted by the luminescent element, i.e. the phosphor, into light with longer wavelengths, and the second electromagnetic radiation converted by the phosphor contribute to the usable wavelength range of the spectrometer. That is to say, in particular, that the electromagnetic radiation emitted by the light-emitting diode, which is not however converted by the phosphor into light with longer wavelengths, still has a sufficiently high intensity after impinging on the spectrometric measurement region so that it can be registered by the detection unit, and spectral information of the spectrometric measurement region from this wavelength range may therefore also be reliably detected and optionally evaluated. This is advantageous in particular for Fourier-transform spectrometers, since by virtue of their technology they may be used over a large wavelength range. Advantageously, the efficiency of the illumination device for spectrometry applications may therefore be increased.

Because of the broad usable wavelength range of the spectrometer, in which both the emission spectrum of the LED and the emission spectrum of the luminescent element are usable for the spectrometry, in particular material or object identification with the aid of the spectral data registered by the spectrometer is possible with a high reliability and measurement of concentrations of constituents is possible with a high accuracy.

Very high light intensities may constitute a risk in terms of eye safety. For instance, the eye may be damaged by thermal or photochemical effects. The biological effect on the eye and the risk potential is highly wavelength-dependent. Blue light (wavelength between 400 nm and 500 nm) has a much greater risk potential in terms of thermal and photochemical eye damage than light of longer wavelengths (for example red light or NIR light). A further advantage is therefore that the spectrometer allows safe use even by untrained users.

In one embodiment, the first central wavelength of the light-emitting diode may be 550 nanometers (nm) or 1000 nm or have a value between 550 nm and 1000 nm. As an alternative, the first central wavelength of the light-emitting diode may be 760 nm or 2500 nm or have a value between 760 nm and 2500 nm. As an alternative, the first central wavelength of the light-emitting diode may be 610 nm or 3000 nm or have a value between 610 nm and 3000 nm. As an alternative, the first central wavelength of the light-emitting diode may be 610 nm or 1000 nm or have a value between 610 nm and 1000 nm. Red-emitting light-emitting diodes having central wavelengths of about 625 nm to 700 nm are very efficient in the conversion of electrical power into optical power. In particular, GaAs-based material systems having central wavelengths of up to 1020 nm may be produced much more economically than InGaAs-based systems, which need to be used for the wavelength range of more than 1020 nm.

The light-emitting diode (LED) is in particular an LED emitting in the red or near infrared wavelength range. The red wavelength range comprises wavelengths of between 610 nm and 760 nm, inclusive of 610 nm and 760 nm. The near infrared wavelength range comprises wavelengths of from 760 nm to 3000 nm, inclusive of the interval limits. The color of an LED depends, in particular, on the semiconductor material used or the bandgap of the semiconductor material. Red LEDs may for example comprise aluminum gallium arsenide (AlGaAs), gallium phosphide (GaP), gallium arsenide phosphide (GaAsP), aluminum gallium indium phosphide (AlGaInP), etc. Near infrared LEDs may for example comprise aluminum gallium arsenide (AlGaAs), gallium arsenide (GaAs) etc. as semiconductor material.

The spectrum of an LED can usually be described to a good approximation by a Gaussian function. The spectrum of a light-emitting diode is usually expressed by a single wavelength, for example a central wavelength of the LED. The central wavelength describes the wavelength which lies midway between two points (wavelengths) having a spectral density of 50% of the peak of the spectrum, i.e. 50% of the maximum of the spectrum. For a symmetrical spectrum, the central wavelength corresponds precisely to the wavelength at which the spectrum is maximal.

The luminescent element may comprise one or more phosphors. Examples of phosphors are described inter alia in “Sunlight-activated long-persistent luminescence in the near-infrared from Cr3+-doped zinc gallogermanates”, (Pan et al., Nature Materials 11, 58-63 (2012)). The luminescent element can be excited by the LED to emit electromagnetic radiation. Typical phosphors are based on garnets, silicates, oxynitrides or oxycarbonitrides, or nitrides or carbonitrides. In particular, the luminescent element can be excited by the LED to emit electromagnetic radiation in the near infrared range, for example in the range of from 550 nm to 1100 nm, in the range of from 1150 nm to 1800 nm or in the range of from 850 nm to 1700 nm. In particular embodiments, an additional efficient phosphor, which broadens the emission of the LED somewhat and the emission range of which may lie entirely in the excitation range of the NIR phosphor, may likewise be used.

The spectrometric measurement region may, for example, be an object which is intended to be studied by means of the spectrometer in relation to its spectral properties, or a section of an object, and the object may for example comprise a gaseous, liquid and/or solid medium. The object may have a homogeneous or heterogeneous composition.

Spectral data of the spectrometric measurement region may be registered by the electromagnetic radiation coming from the spectrometric measurement region, i.e. for example the electromagnetic radiation emitted, reflected, transmitted and/or scattered by the spectrometric measurement region, being detected by the spectrometer, or the detection unit of the spectrometer.

The illumination device and/or the detection unit may comprise the spectral element. As an alternative or in addition, the spectral element may be configured as a separate component. The spectral element may be arranged in the beam path between the illumination device and the spectrometric measurement region. As an alternative or in addition, the spectral element may be arranged in the beam path between the spectrometric measurement region and the detection unit. The spectral element may for example comprise a tunable Fabry-Perot interferometer (FPI), birefringent crystals and polarizers, or another wavelength-selective filter, as well as optionally optical lenses, optical apertures, microlenses, microlens arrays, beam splitters, mirrors, micromirrors, etc. The spectrometer may, for example, be configured as a static or mobile Fourier-transform spectrometer or as a Fabry-Perot spectrometer.

The illumination device, the spectral element and the detection unit of the spectrometer may, for example, be arranged in a transmission geometry or in a reflection geometry. For transmission measurements, in particular electromagnetic radiation which has been transmitted by the spectrometric measurement region to be studied is registered, the transmitted electromagnetic radiation comprising spectral information relating to the spectrometric measurement region. The transmitted electromagnetic radiation may be detected wavelength-selectively by means of the spectral element and the detection unit and provide conclusions relating to the spectral composition of the spectrometric measurement region. The illumination device and the detection unit are in this case arranged on mutually averted sides in relation to the spectrometric measurement region. For reflection measurements, in particular electromagnetic radiation which has been reflected by the spectrometric measurement region to be studied is registered, the reflected electromagnetic radiation comprising spectral information relating to the spectrometric measurement region. The reflected electromagnetic radiation may be detected wavelength-selectively, and may provide conclusions relating to the spectral composition of the spectrometric measurement region. The illumination device and the detection unit are in this case arranged on a common side in relation to the spectrometric measurement region, the detection unit being arranged in such a way that, in particular, the electromagnetic radiation coming from the illumination device and reflected by the spectrometric measurement region impinges on the detection unit and can be registered by it.

The detection unit may in one embodiment be a detector element or a detector array, which comprises a plurality of detector elements. A radiation sensor, for example based on silicon (Si), germanium (Ge), germanium on silicon, indium gallium arsenide (InGaAs), lead selenite (PbSe) may be used as a detector element. For example, photodiodes or bolometers are also suitable as radiation sensors. Radiation sensors may, as a function of a property of the electromagnetic radiation impinging on the radiation sensor, output an electrical detection signal which is a measure of the radiation property. Radiation sensors may, for example, measure an intensity or an energy flux density of the electromagnetic radiation coming from the spectrometric measurement region.

In one embodiment, the detection unit may be configured to spectrally evaluate the electromagnetic radiation, which comprises the spectral data, coming from the spectrometric measurement region. The spectral data may, for example, comprise a spectrum or sections of a spectrum. For example, the spectral data may comprise an intensity profile which is plotted as a function of the wavelength, time or position, or a profile of an electrical signal. The detection signal may for example comprise an electrical signal. For example, spectral information may be determined from the detection signal by means of a computer algorithm and reference data stored in a memory, for example reference spectra or sections of reference spectra. The spectrometric evaluation may take place in the spectrometer, in a mobile terminal which comprises the spectrometer, and/or in an evaluation unit arranged externally in relation to the spectrometer, for example a cloud.

The mobile terminal may comprise a computation unit which is adapted to process signals or data, a storage unit which is adapted to store signals or data, a communication interface for reading in and/or outputting data, and a display unit which is adapted to display information and/or measurement results. The computation unit may, for example, comprise a processor or a microcontroller. The communication interface may be configured to read in or output data wirelessly and/or via a cable. For example, the mobile terminal may be a smartphone, in the storage unit of which a software application (app) may be stored, or the app may be downloadable or available online. The app may be adapted to carry out a measurement by means of the spectrometer. The measurement results, or results of a spectrometric evaluation of the measurement results, may for example be output to the user via a display device of the mobile terminal. Possible display devices are for example display screens or loudspeakers, by means of which optical, haptic or acoustic outputs may take place. The result of the spectrometric evaluation, i.e. spectral information of the spectrometric measurement region, may for example be information relating to a chemical composition of the spectrometric measurement region, a presence and/or a concentration of at least one chemical substance in the spectrometric measurement region, or an identification of the spectrometric measurement region.

In one embodiment, the spectrometer is distinguished in that the luminescent element is arranged on the light-emitting diode. In particular, the luminescent element may be arranged directly as a layer on the light-emitting diode. One advantage is that this allows a very compact structure of the spectrometer.

As an alternative or in addition, the luminescent element may be arranged as a so-called remote phosphor on a separate carrier. One advantage is that this allows uniform illumination of the spectrometric measurement region. Furthermore, heating of the luminescent element, i.e. of the phosphor, is reduced so that the spectral stability of the luminescent element may be increased. A reliable spectrometer may therefore be provided. The carrier may for example comprise a holding structure or an optical element, for example an optical lens, a diffuser or a directional diffuser. A directional diffuser is a diffuser having technically adapted scattering characteristics.

According to one embodiment, the luminescent element may comprise at least one further phosphor for converting the first fraction of the first electromagnetic radiation having the first spectrum into third electromagnetic radiation having a third spectrum, and a first phosphor for converting the third electromagnetic radiation having the third spectrum into the second electromagnetic radiation having the second spectrum. One advantage is that the emission spectrum of the illumination device may therefore be optimized further, so that it is possible to produce a spectrum having a maximally constant intensity or power over the wavelength range usable for the spectrometric measurement.

According to one embodiment, the illumination device comprises a package in which the light-emitting diode is arranged. In particular, the light-emitting diode is arranged in an SMD package (SMD=surface-mount device). As an alternative or in addition, an optical element which influences the light propagation may be arranged on or in the package, in particular the SMD package. The optical element may in one embodiment comprise at least one of the following components and/or a plurality of the same type of the following components: diffuser, directional diffuser, reflector, mirror, micromirror, optical lens. One advantage is that the light propagation of the illumination device may therefore be optimized for the spectrometry.

According to one embodiment, the detection unit may comprise a computation unit which is adapted to register, by means of the electromagnetic radiation coming from the spectrometric measurement region, a spectrum and/or to determine spectral information of the spectrometric measurement region.

According to one embodiment, the spectrometer is a miniature spectrometer. The miniature spectrometer is a spectrometer which has dimensions in the centimeter range, particularly in the range of less than 10 cm and more than 1 cm or less. For example, the miniature spectrometer is greater than or equal to 1 cm³ and less than or equal to 1000 cm³. As an alternative or in addition, the miniature spectrometer may also be less than or equal to 1 cm³ and greater than or equal to 0.01 cm³. As an alternative or in addition, the miniature spectrometer may also be less than or equal to 100 cm³ and greater than or equal to 0.01 cm³. One advantage is that an efficient, compact and transportable spectrometer may therefore be provided.

A method for calibrating the spectrometer is distinguished in that the first central wavelength of the light-emitting diode is used as a reference for the wavelength calibration of the detection unit. The excitation wavelength, that is to say the first central wavelength of the light-emitting diode, may be assumed to be known. Since the detection unit is sensitive for electromagnetic radiation in the red or near infrared wavelength range, and because the first central wavelength of the LED also lies in this wavelength range, the detection unit can detect the electromagnetic radiation emitted by the LED and assign the known wavelength thereto for the wavelength calibration. As an alternative or in addition, the method is distinguished in that the emitted intensity of the light-emitting diode is used as a power reference for the spectrometric measurement for the power calibration. One advantage, besides the advantages mentioned for the spectrometer, is that the reliability of the measurement results of the spectrometer can therefore be increased.

### BRIEF DESCRIPTION OF THE DRAWINGS

Exemplary embodiments of the invention are represented in the drawings and will be explained in more detail in the following description. References which are the same in the figures denote elements which are the same or have the same effect.

FIG. 1 shows a cross section of an illumination device according to one exemplary embodiment,

FIG. 2 shows a cross section of an illumination device according to one exemplary embodiment,

FIG. 3 shows a first spectrum of a light-emitting diode according to one exemplary embodiment,

FIG. 4 shows an excitation spectrum of a light-emitting diode and an emission spectrum of a phosphor, the excitation spectrum and the emission spectrum not having an overlap,

FIG. 5 shows an outline of a first spectrum of a light-emitting diode and of a second spectrum of a luminescent element in a common coordinate system according to one exemplary embodiment, the first spectrum and the second spectrum having an overlap,

FIG. 6 shows an outline of an emission spectrum of an illumination device according to one exemplary embodiment, the first spectrum of the light-emitting diode and the second spectrum of the luminescent element corresponding to the first spectrum shown in FIG. 5 and the second spectrum shown in FIG. 5,

FIG. 7 shows a spectrometer in a reflection geometry according to one exemplary embodiment,

FIG. 8 shows a spectrometer in a transmission geometry according to one exemplary embodiment, and

FIG. 9 shows a flowchart of a method for calibrating the spectrometer according to one exemplary embodiment.

### EXEMPLARY EMBODIMENTS OF THE INVENTION

A spectrometer 1000 comprises an illumination device 100 for illuminating a spectrometric measurement region 104, a detection unit 106 for detecting electromagnetic radiation 1004 coming from the spectrometric measurement region, and a spectral element 105 which is arranged in the beam path between the illumination device 100 and the detection unit 106.

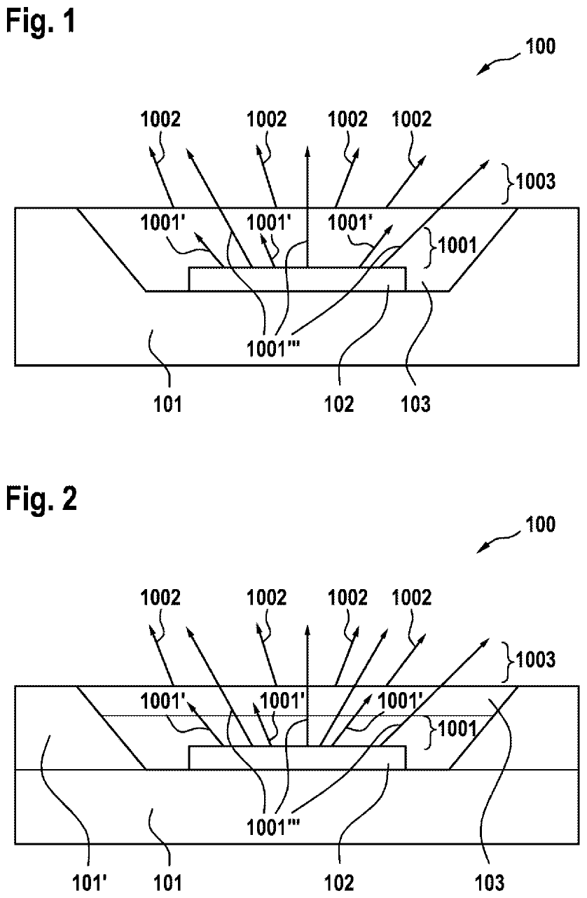

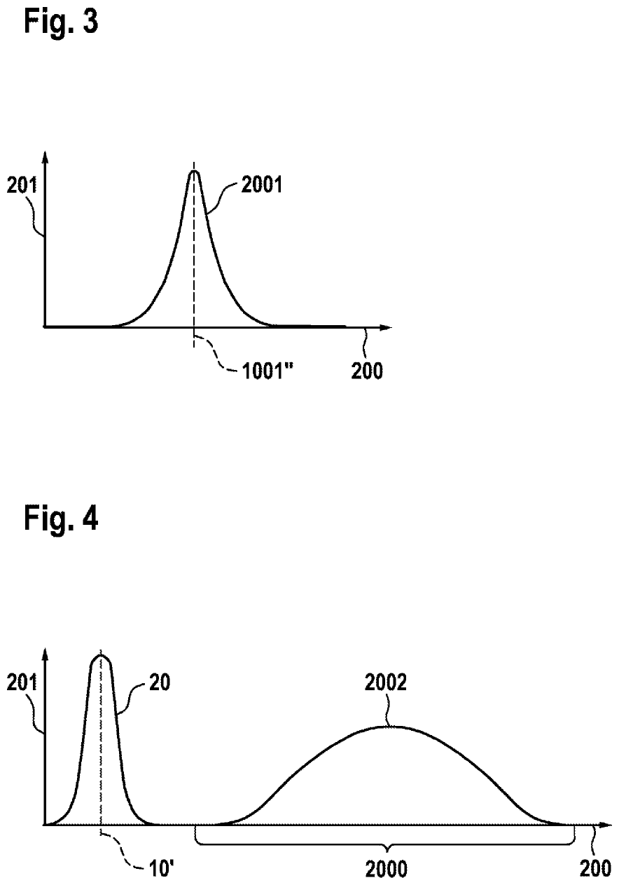

FIG. 1 shows a cross section of the illumination device 100 according to one exemplary embodiment. A light-emitting diode 102 is arranged on a substrate 101. In FIG. 1, the substrate 101 comprises a recess in which the light-emitting diode 102 is arranged. The luminescent element 103 is arranged on the light-emitting diode 102 in the recess. The light-emitting diode 102 having a first central wavelength 1001″ is adapted to emit first electromagnetic radiation 1001 having a first spectrum 2001, the first spectrum having for example the Gaussian profile shown in FIG. 3. The first electromagnetic radiation 1001 passes through the luminescent element 103, the luminescent element 103 being adapted to convert a first component 1001′ of the first electromagnetic radiation 1001 into second electromagnetic radiation 1002 having a second spectrum 2002. That is to say, the luminescent element 103 comprises at least one phosphor which can be excited by the first electromagnetic radiation 1001 to emit the second electromagnetic radiation 1002. Not all energy states of charge carriers are allowed in the phosphor. Electronic bands or band structures that define which energies various charge carriers can have, and which they cannot, are therefore often referred to. In these band structures, energy bands or states may additionally be generated by deliberate introduction of extraneous atoms (also referred to as activators). The fundamental mode of action of the luminescent element 103 is based on the physical principle of luminescence. The light generation in this case takes place by excitation of an electron with the energy of the first electromagnetic radiation 1001 impinging on the luminescent element 103. The electron is thereby transported from a low energy state (valence band) into a higher energy state (generated by activators) or the so-called conduction band. A hole in the valence band is also created by this process. After a certain time, the electron releases its energy by emitting light and returns into the valence band. The second spectrum 2002 of the second electromagnetic radiation 1002 converted in this way is dependent on the band structure of the phosphor and on the activators. A second fraction 1001′″ of the first electromagnetic radiation 1001 passes through the luminescent element 103 without being converted. The emission spectrum 1003 of the illumination device is therefore given by a superposition of the spectrum of the unconverted second fraction 1001′″ of the first electromagnetic radiation 1001 and of the second spectrum 2002 of the converted first fraction 1001′, i.e. of the second electromagnetic radiation 1002. An exemplary profile of the emission spectrum 2004 of the illumination device 100 according to one exemplary embodiment is represented in FIG. 6.

As an alternative to the exemplary embodiment shown in FIG. 1, the light-emitting diode 102 may also be arranged on a substrate without a recess, and the luminescent element 103, which acts as a phosphor of the illumination device, may be applied onto the light-emitting diode 102, for example as a layer or coating.

One difference between the exemplary embodiment shown in FIG. 1 and the exemplary embodiment shown in FIG. 2 is that the luminescent element 103 is arranged directly on the light-emitting diode 102 in FIG. 1, while the luminescent element 103 is arranged as a so-called remote phosphor on a separate carrier 101′ in FIG. 2. In the exemplary embodiment shown in FIG. 2, the luminescent element 103 is kept separated from the light-emitting diode 102 by the carrier 101′. The carrier 101′ holds the luminescent element 103 at a distance above the substrate 101. The light-emitting diode 103 is arranged on the substrate 101, between the luminescent element 103 and the substrate 101.

For example, the light-emitting diode 103 may be arranged in a package, for example an SMD package. At least one optical element (for example a diffuser, directional diffuser, reflector, mirror, micromirror, optical lens), which influences and/or manipulates the light propagation, may likewise be fastened on the SMD package. The luminescent element 103 is conventionally applied on the light-emitting diode 103, as shown for example in FIG. 1, as a remote phosphor on a separate carrier 101′, as shown for example in FIG. 2, or it may for example also be arranged or applied on the optical element.

As an alternative or in addition, further optical elements may also be applied on the package or in the beam path between the LED package and the spectrometric measurement region. For example, the light propagation of the light source may be optimized for the spectrometry by a diffuser or directional diffuser or a (further) optical lens.

In FIG. 3, the first spectrum 2001, i.e. an emission spectrum of the light-emitting diode 102 before a fraction of the first electromagnetic radiation 1001 is converted by the luminescent element 103, is outlined according to one exemplary embodiment. The wavelength is plotted on the x axis 200 and the intensity or spectral ray density is plotted on the y axis 201. The first spectrum 2001 in this case has a profile similar to a Gaussian function. The spectrum 2001 of light-emitting diodes is usually expressed by a single wavelength, for example a central wavelength 1001″ of the light-emitting diode 102. The central wavelength 1001″ describes the wavelength which lies midway between two points (wavelengths) having a spectral density of 50% of the peak of the spectrum, i.e. 50% of the maximum of the spectrum. For a symmetrical spectrum such as the first spectrum 2001 shown in FIG. 3, the central wavelength 1001″ corresponds precisely to the wavelength at which the spectrum is maximal.

In FIG. 4, an excitation spectrum 20 of a light-emitting diode and an emission spectrum 2002 of a phosphor as described in the prior art are outlined, the excitation spectrum and the emission spectrum not having an overlap. The phosphor used in this case is excited with blue light (central wavelength 10′ of for example 460 nm, 490 nm or a value between 460 nm and 490 nm) and then emits electromagnetic radiation in the near infrared range, particularly in the range of from 700 nm to 1050 nm. A part of the blue light is not converted and therefore remains in the emission spectrum of an illumination device having a blue LED and the phosphor from the prior art described in this example, this light fraction lying outside the wavelength interval 2000 which is usually registered in a spectrometric measurement.

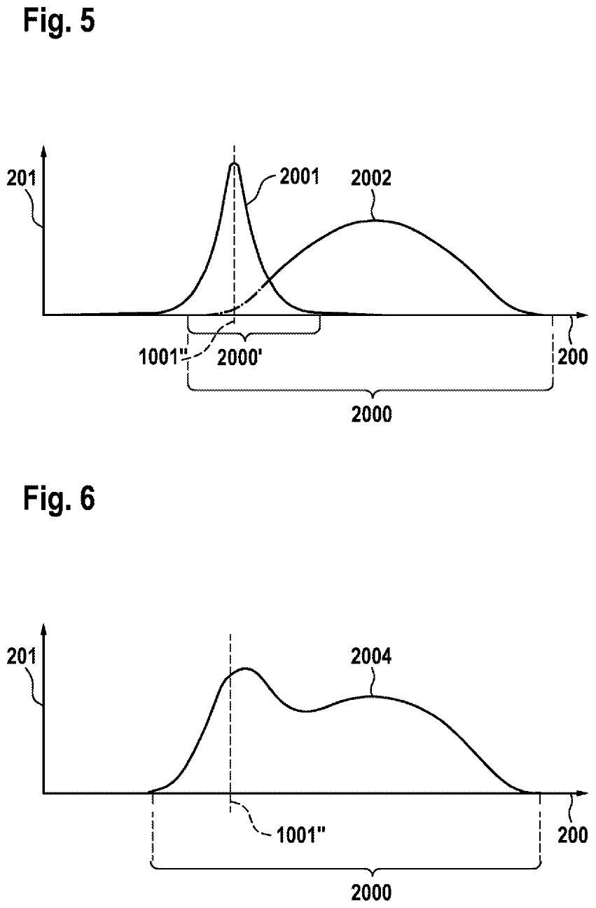

In FIG. 5, the first spectrum 2001, i.e. an emission spectrum of the light-emitting diode 102, which acts as an excitation spectrum for the luminescent element 103, and the second spectrum 2002, which describes the emission spectrum of the luminescent element 103 after excitation by the first electromagnetic radiation 1001′, are outlined by way of example according to one exemplary embodiment in a common coordinate system. The wavelength is plotted on the x axis 200 and the intensity or spectral ray density is plotted on the y axis 201. A wavelength range 2000 which is usable for spectrometry is plotted on the x axis. Typical wavelength intervals within which a significant photocurrent is generated are 400 nm to 1100 nm for photodetectors based on silicon, 600 nm or 900 nm to 1700 nm for photodetectors based on indium gallium arsenide (In_{0.53}Ga_{0.47}As), and 900 nm to at most 2600 nm for photodetectors based on indium gallium arsenide (InₓGa₁₋ₓAs; with x>0.53). The first central wavelength 1001″ of the light-emitting diode 102 in this case lies in the wavelength interval 2000 which is usable for spectrometry. As represented in FIG. 5, the first spectrum 2001 and the second spectrum 2002 have an overlap 2000′. In this way, it is in particular possible, in addition to the emission spectrum 2002 of the luminescent element 103, also to use the spectrum of the light-emitting diode 102 for spectrometry. The curve profile of the second spectrum 2002 depends, in particular, on the chemical composition of the luminescent element 103.

The spectrometer 1000 comprises the illumination device 100, the light-emitting diode 102 according to one exemplary embodiment having the first central wavelength with a value of 630 nm, a near infrared phosphor, which emits the second electromagnetic radiation 1002 having the second spectrum 2002 with wavelengths in the range of from 700 nm to 1100 nm, being used as the luminescent element 103. Typical phosphors are based for example on garnets, silicates, oxynitrides or oxycarbonitrides, or nitrides or carbonitrides. The emission spectrum 2004 of the illumination device 100 in this exemplary embodiment comprises electromagnetic radiation having wavelengths in the interval of from 600 nm to 1100 nm. The entire emission spectrum 2004 therefore lies in the wavelength interval 2000 usable for spectrometry and has an approximately constant power in this wavelength range, and in particular electromagnetic radiation of all wavelengths in the usable wavelength interval 2000 is directed with a sufficient power onto an object which is intended to be spectrometric studied, so that the reliability of the measurement results of the detection unit 106 for the wavelengths of the wavelength interval 2000 can be increased.

The first central wavelength 1001″ of the light-emitting diode 103 may, for example, be 550 nanometers (nm) or 1000 nm or have a value between 550 nm and 1000 nm. As an alternative, the first central wavelength 1001″ of the light-emitting diode 102 may be 760 nm or 2500 nm or have a value between 780 nm and 2500 nm. As an alternative, the first central wavelength 1001″ of the light-emitting diode 102 may be 610 nm or 3000 nm or have a value between 610 nm and 3000 nm. As an alternative, the first central wavelength 1001″ of the light-emitting diode 102 may be 610 nm or 1000 nm or have a value between 610 nm and 1000 nm. As an alternative, the first central wavelength 1001″ may be 580 nm, 630 nm, 800 nm or 1200 nm.

In a further exemplary embodiment, the light-emitting diode 102 of the illumination device 100 of the spectrometer 1000 has the first central wavelength 1001″ with a value of 1200 nm, and the luminescent element 103 comprises a phosphor which emits the second electromagnetic radiation 1002 having the second spectrum 2002 with wavelengths in the range of from 1280 nm to 1800 nm. The emission spectrum 2004 of the illumination device 100 in this exemplary embodiment therefore comprises wavelengths of from 1150 nm to 1800 nm. The entire emission spectrum 2004 therefore lies in the wavelength interval 2000 usable for spectrometry and has an approximately constant power in this wavelength range, and in particular electromagnetic radiation of all wavelengths in the usable wavelength interval 2000 is directed with a sufficient power onto an object which is intended to be spectrometric studied, so that the reliability of the measurement results of the detection unit 106 for the wavelengths of the wavelength interval 2000 can be increased.

In a further version of the spectrometer 1000, a light-emitting diode 102 having 800 nm as the first central wavelength may be used. The luminescent element 103 may comprise a plurality of phosphors, which in total emits the second electromagnetic radiation 1002 having the second spectrum 2002 with wavelengths in the range of from 850 to 1700 nm.

In FIG. 6, an outline of the emission spectrum 2004 of the illumination device 100 according to one exemplary embodiment is shown, the first spectrum 2001 of the light-emitting diode 102 and the second spectrum 2002 of the luminescent element 103 corresponding to the first spectrum 2001 shown in FIG. 5 and the second spectrum 2002 shown in FIG. 5. The wavelength is plotted on the x axis 200 and the intensity or spectral ray density is plotted on the y axis 201. The curve profile generally depends on the chemical composition of the luminescent element 103 and on the light-emitting diode 102 used, in particular the first central wavelength 1001″ of the light-emitting diode 102. The emission spectrum 2004 of the illumination device 100 is given by a superposition of the spectra of the unconverted second fraction 1001′″ of the first electromagnetic radiation 1001 and of the second electromagnetic radiation 1002 emitted by the luminescent element 103.

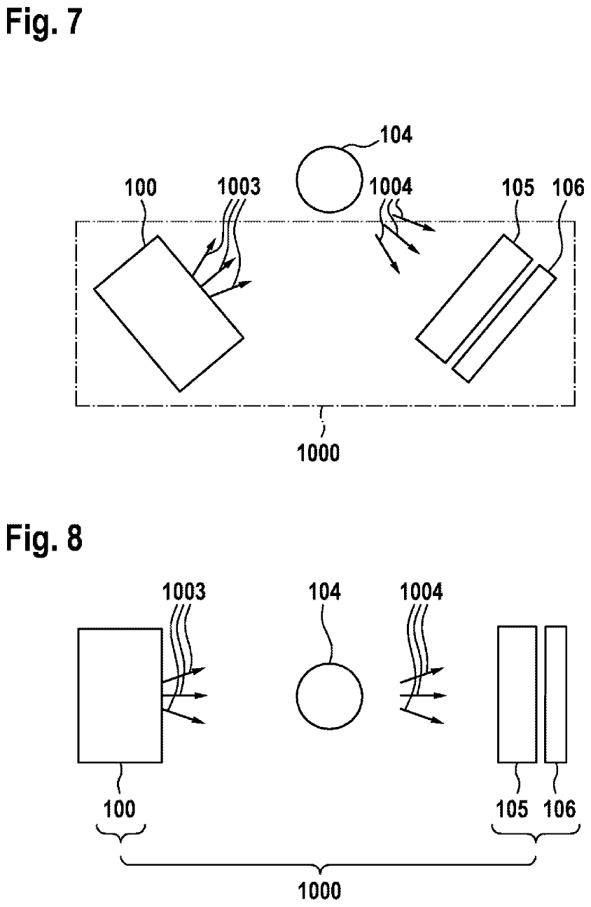

FIG. 7 shows an exemplary embodiment in which the spectrometer 1000 is represented in cross section and is arranged in a reflection geometry. The illumination device 100, which for example has the same structure as the illumination device 100 shown in FIG. 1 or FIG. 2, and the detection unit 106 are arranged on a common side in relation to the spectrometric measurement region 104 in the reflection geometry, the detection unit 106 being arranged in such a way that, in particular, the electromagnetic radiation emitted 1003 by the illumination device 100 and reflected 1004 by the spectrometric measurement region 104 impinges on the detection unit 106 and can be registered by it. The detection unit 106 may for example comprise a detector element or a detector array, which comprises a plurality of detector elements. A radiation sensor, for example based on silicon (Si), germanium (Ge), germanium on silicon, indium gallium arsenide (InGaAs), lead selenite (PbSe) may be used as a detector element. For example, photodiodes or bolometers are also suitable as radiation sensors. Radiation sensors may, as a function of a property of the electromagnetic radiation impinging on the radiation sensor, output an electrical detection signal which is a measure of the radiation property. Radiation sensors may, for example, measure an intensity or an energy flux density of the electromagnetic radiation coming from the spectrometric measurement region. The spectral element 105 is arranged in FIG. 7 as a separate component in the beam path between the spectrometric measurement region 105 and the detection unit 106. In one exemplary embodiment, the detection unit 106 or the illumination device 100 may comprise the spectral element 105 or the spectral element 105 may be arranged in the beam path between the illumination device 100 and the measurement region 104.

FIG. 8 shows an exemplary embodiment in which the spectrometer 1000 is represented in cross section and is arranged in a transmission geometry. The illumination device 100, which for example has the same structure as the illumination device 100 shown in FIG. 1 or FIG. 2, and the detection unit 106 are arranged on mutually opposite sides of the spectrometric measurement region 104 in relation to the spectrometric measurement region 104. That is to say, the spectrometric measurement region 104 is arranged between the illumination device 100 and the detection unit 106. The spectral element 105 may, as described above in connection with FIG. 7, be configured as part of the illumination device 100 or as part of the detection unit 106, or it may be arranged as a separate component in the beam path between the illumination device 100 and the spectrometric measurement region 104.

The spectral element 105 may for example comprise a tunable Fabry-Perot interferometer (FPI), birefringent crystals and polarizers, or another wavelength-selective filter, as well as optionally optical lenses, optical apertures, microlenses, microlens arrays, beam splitters, mirrors, micromirrors, etc. The spectrometer 1000 may, for example, be configured as a static or mobile Fourier-transform spectrometer or as a Fabry-Perot spectrometer. The illumination device 100, the spectral element 105 and the detection unit 106 may be arranged in a common package. For example, the spectrometer 1000 may be configured as a portable instrument. For example, the spectrometer 1000 may be configured as a miniature spectrometer. In one exemplary embodiment, the spectrometer 1000 may be integrated into a mobile terminal, for example a smartphone.

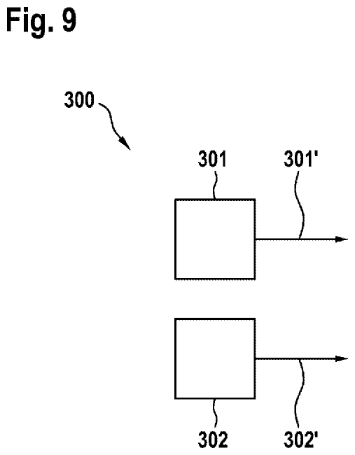

In FIG. 9, a flowchart of a method 300 for calibrating the spectrometer 1000 is represented. The spectrometer comprises, for example, the illumination device 100 shown FIG. 1 or FIG. 2. The known emission spectrum of the light-emitting diode 102 may be used to calibrate the spectrometer 100, since because of the selection of the central wavelength the detection unit is sensitive to the first electromagnetic radiation 1001 which is emitted by the light-emitting diode. The method may comprise a wavelength calibration 301 and/or a power calibration 302.

In the method 300 represented in FIG. 9, both the wavelength calibration 301 and the power calibration 302 are represented in the flowchart. In the wavelength calibration 301, use is made of the fact that the first central wavelength 1001″ of the light-emitting diode 102 is known. During the wavelength calibration, the detection unit 106 registers the first electromagnetic radiation 1001′ having the first spectrum 2002, the value of the known first central wavelength 1001″ being assigned to the central wavelength of the spectrum registered. For example, a reference data set 301′, which may be applied to the measurement result of the spectrometric measurement, can therefore be generated. In the power calibration 302, the emitted intensity of the light-emitting diode 102 is used as a power reference 302′ for the spectrometric measurement. To this end, the measured spectrum is evaluated in terms of the LED intensity reflected by the object being studied. For example, the measured LED intensity may be compared with a 100% reflection stored in the electronics, so that an absolute value of the reflected intensity for this wavelength is obtained. In a further example, the LED intensity measured during a test exposure may be used in order to prevent saturation of the photodiodes during the subsequent measurement. In a further example, the spectrum is recorded repeatedly, so that the variation in the LED intensity allows conclusions about a modified measurement condition (for example change of the measurement distance, the measurement angle, of the object being studied, or the like).

1. A spectrometer comprising:
an illumination device configured to illuminate a spectrometric measurement region;
a detection unit configured to detect electromagnetic radiation coming from the spectrometric measurement region; and
a spectral element arranged in a beam path between the illumination device and the detection unit,
wherein the illumination device comprises
a light-emitting diode having a first central wavelength and adapted to emit first electromagnetic radiation having a first spectrum, and
a luminescent element configured to convert a first fraction of the first electromagnetic radiation having the first spectrum into second electromagnetic radiation having a second spectrum
and wherein
the first central wavelength has a value in a range of 550 nm to 3000 nm, and
the first spectrum and the second spectrum have an overlap.

2. The spectrometer as claimed in claim 1, wherein the luminescent element is arranged in the beam path.

3. The spectrometer as claimed in claim 1, wherein the luminescent element comprises:
at least one further phosphor configured to convert the first fraction of the first electromagnetic radiation having the first spectrum into third electromagnetic radiation having a third spectrum; and
a first phosphor configured to convert the third electromagnetic radiation having the third spectrum into the second electromagnetic radiation having the second spectrum.

4. The spectrometer as claimed in claim 1, wherein the luminescent element is applied as a coating on the light-emitting diode.

5. The spectrometer as claimed in claim 1, wherein the luminescent element is applied on one of a carrier and an optical element.

6. The spectrometer as claimed in claim 1, wherein the illumination device comprises a package in which the light-emitting diode is arranged.

7. The spectrometer as claimed in claim 1, wherein the illumination device comprises at least one optical element configured to adjust a propagation of electromagnetic radiation.

8. The spectrometer as claimed in claim 5, wherein the optical element comprises at least one of the following components:
a diffuser;
a directional diffuser;
a reflector;
a mirror;
a micromirror; and
an optical lens.

9. The spectrometer as claimed in claim 1, wherein the detection unit comprises:
a computation unit configured to determine, using the electromagnetic radiation coming from the spectrometric measurement region, at least one of a spectrum and a spectral information of the spectrometric measurement region.

10. The spectrometer as claimed in claim 1, wherein the first central wavelength has a value in a range of 550 nm to and 1800 nm.

11. The spectrometer as claimed in claim 1, wherein the spectrometer is a miniature spectrometer.

12. A method for calibrating a spectrometer, comprising:
providing a spectrometer including
an illumination device configured to illuminate a spectrometric measurement region, the illumination device including
a light-emitting diode having a first central wavelength and adapted to emit first electromagnetic radiation having a first spectrum with a value in a range of 550 nm to 3000 nm, and
a luminescent element configured to convert a first fraction of the first electromagnetic radiation having the first spectrum into second electromagnetic radiation having a second spectrum, the first spectrum and the second spectrum having an overlap,
a detection unit configured to detect electromagnetic radiation coming from the spectrometric measurement region, and
a spectral element arranged in a beam path between the illumination device and the detection unit and
at least one of using the first central wavelength of the light-emitting diode as a reference for wavelength calibration of the detection unit, and using an emitted intensity of the light-emitting diode as a power reference for the spectrometric measurement for the power calibration.
